(19) United States
(12) Patent Application Publication
(10) Pub. No.: US 2014/0182653 A1
(43) Pub. Date: Jul. 3, 2014

(54) SOLAR CELL AND SOLAR CELL MODULE USING THE SAME

(71) Applicant: Gi Gon Park, Jung-gu (KR)

(72) Inventor: Gi Gon Park, Jung-gu (KR)

(73) Assignee: LG INNOTEK CO., LTD., Seoul (KR)

(21) Appl. No.: 14/236,823

(22) PCT Filed: Jul. 13, 2012
(86) PCT No.: PCT/KR2012/005586

§ 371 Date: Feb. 4, 2014

(30) Foreign Application Priority Data
Aug. 1, 2011 (KR) 10-2011-0076751

(51) Int. Cl. H01L 31/0236; H01L 31/05

(52) U.S. Cl. CPC H01L 31/02363; H01L 31/0516
USPC 136/244; 136/256; 438/81

(57) ABSTRACT

Disclosed are a solar cell and a solar cell module using the same. The solar cell according to the embodiment includes a stepped portion on a support substrate; a back electrode layer having a first height difference on the support substrate and the stepped portion; a light absorbing layer having a second height difference on the back electrode layer; and a front electrode layer having a third height difference on the light absorbing layer. The solar cell module according to the embodiment includes a stepped portion on a support substrate; a first solar cell on the support substrate; and a second solar cell on the stepped portion, wherein the first solar cell is electrically connected to the second solar cell on a lateral side of the stepped portion.

### TECHNICAL FIELD

The embodiment relates to a solar cell and a solar cell module using the same.

### BACKGROUND ART

Recently, the development of new renewable energy has become more important and interested due to the serious environmental pollution and the lack of fossil fuel. Among the new renewable energy, a solar cell is spotlighted as a pollution-free energy source for solving the future energy problem because it rarely causes environmental pollution and has the semi-permanent life span and there exists infinite resources for the solar cell.

olar cells may be defined as devices to convert light energy into electric energy by using a photovoltaic effect of generating electrons when light is incident onto a P-N junction diode. The solar cell may be classified into a silicon solar cell, a compound semiconductor solar cell mainly including a group I-III-VI compound or a group III-V compound, a dye-sensitized solar cell, and an organic solar cell according to materials constituting the junction diode.

A solar cell made from CIGS (CuInGaSe), which is one of group I-III-VI Chal-copyrite-based compound semiconductors, represents superior light absorption, higher photoelectric conversion efficiency with a thin thickness, and superior electro-optic stability, so the CIGS solar cell is spotlighted as a substitute for a conventional silicon solar cell.

In general, the CIGS solar cell can be fabricated by sequentially forming a back electrode layer, a light absorbing layer, a buffer layer and a front electrode layer on a glass substrate. The substrate can be prepared by using various materials, such as soda lime glass, stainless steel and polyimide (PI). Molybdenum (Mo) is mainly used as a material for the back electrode layer because the Mo has the low specific resistance and thermal expansion coefficient similar to that of the glass substrate.

The light absorbing layer is a P type semiconductor layer and mainly includes CuInSe₂ or Cu(InₓGa₁₋ₓ)Se₂, which is obtained by replacing a part of In with Ga. The light absorbing layer can be formed through various processes, such as an evaporation process, a sputtering process, a selenization process or an electroplating process.

The buffer layer is disposed between the light absorbing layer and the front electrode layer, which represent great difference in lattice coefficient and energy bandgap, to form a superior junction therebetween. The buffer layer mainly includes cadmium sulfide prepared through chemical bath deposition (CBD).

The front electrode layer is an N type semiconductor layer and forms a PN junction with respect to the light absorbing layer together with the buffer layer. In addition, since the front electrode layer serves as a transparent electrode at a front surface of the solar cell, the front electrode layer mainly includes aluminum-doped zinc oxide (AZO) having the superior light transmittance and electric conductivity. The structure of the CIGS solar cell and fabrication method thereof are disclosed in Korean Patent Registration No. 10-0999810, in detail.

The minimum unit of the solar cell is called a cell. In general, one cell generates a very small voltage of about 0.5V to about 0.6V. Therefore, a solar cell module, which is fabricated in the form of a panel by connecting a plurality of cells to each other in series on a substrate to generate voltages in a range of several voltages V to several hundreds of voltages V, is used.

FIG. 1 is a sectional view showing a solar cell module according to the related art. Referring to FIG. 1, a front electrode layer 60 of a first cell C1 makes contact with a back electrode layer 21 of a second cell C2, so the first cell C1 is connected to the second cell C2. The front electrode layer 60 of the first cell C1 is abruptly bent in the vertical direction and connected to the back electrode layer 21 of the second cell C2. However, if the front electrode layer 60 is bent, it may interfere with the movement of electrons in the front electrode layer 60, so connection resistance between the cells may be increased.

### DISCLOSURE OF INVENTION

### Technical Problem

The embodiment provides a solar cell, which can be readily fabricated and has the improved photoelectric conversion efficiency, and a solar cell module using the same.

### Solution to Problem

A solar cell according to the embodiment includes a stepped portion on a support substrate; a back electrode layer having a first height difference on the support substrate and the stepped portion; a light absorbing layer having a second height difference on the back electrode layer; and a front electrode layer having a third height difference on the light absorbing layer.

A solar cell module according to the embodiment includes a stepped portion on a support substrate; a first solar cell on the support substrate; and a second solar cell on the stepped portion, wherein the first solar cell is electrically connected to the second solar cell on a lateral side of the stepped portion.

A method for fabricating a solar cell module according to the embodiment includes the steps of forming a back electrode layer on a support substrate including a stepped portion; forming a light absorbing layer on the back electrode layer; and forming a front electrode layer on the light absorbing layer.

### Advantageous Effects of Invention

The solar cell according to the embodiment includes the stepped portion formed on the support substrate. Due to the stepped portion, the back electrode layer, the light absorbing layer and the front electrode layer formed on the support substrate may have the height difference, respectively.

In addition, in the case that the solar cell module is formed by connecting a plurality of solar cells, connection electrodes connecting the solar cells with each other can be almost horizontally connected with each other due to the height difference, so the contact area between connection electrodes can be enlarged. That is, the solar cell module according to the embodiment can reduce the contact resistance caused by the bending structure of the connection electrodes and can improve the photoelectric efficiency.

In addition, the roughness pattern is formed in the solar cell module due to the stepped portion. Thus, the adhesive strength between the solar cell module and the layers formed on the solar cell module can be improved, so the solar cell module may have the superior stability and reliability.

### BRIEF DESCRIPTION OF DRAWINGS

FIG. 1 is a sectional view showing a solar cell according to the related art;

FIG. 2 is a sectional view showing a solar cell according to the embodiment;

FIG. 3 is a sectional view showing a stepped portion of a solar cell according to the embodiment;

FIG. 4 is a sectional view showing a solar cell module according to the embodiment; and

FIGS. 5 to 9 are sectional views showing a method for fabricating a solar cell module according to the embodiment.

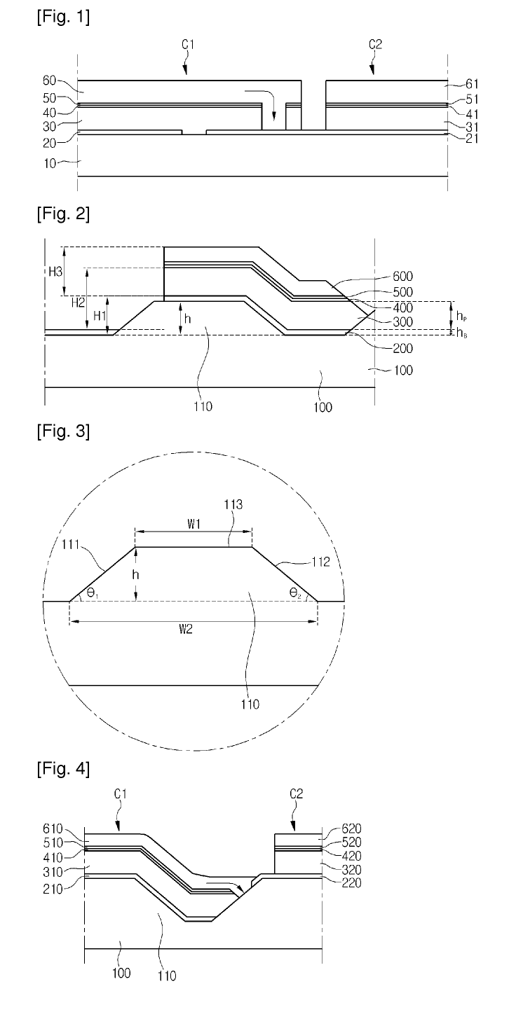

### MODE FOR THE INVENTION

In the description of the embodiments, it will be understood that when a substrate, a layer, a film or an electrode is referred to as being “on” or “under” another substrate, another layer, another film or another electrode, it can be “directly” or “indirectly” on the other substrate, the other layer, the other film, or the other electrode, or one or more intervening layers may also be present. Such a position of the layer has been described with reference to the drawings. The size of the elements shown in the drawings may be exaggerated for the purpose of explanation and may not utterly reflect the actual size.

FIG. 2 is a sectional view showing a solar cell according to the embodiment and FIG. 3 is a sectional view showing a stepped portion of the solar cell according to the embodiment.

Referring to FIG. 2, the solar cell according to the embodiment includes a support substrate 100, a stepped portion 110, a back electrode layer 200, a light absorbing layer 300, a buffer layer 400, a high-resistance buffer layer 500, and a front electrode layer 600.

The support substrate 100 supports the stepped portion 110, the back electrode layer 200, the light absorbing layer 300, the buffer layer 400, the high-resistance buffer layer 500 and the front electrode layer 600.

The support substrate 100 has high strength. For example, the support substrate 100 may include a glass substrate, a ceramic substrate, such as alumina, a stainless steel substrate, a titanium substrate or a polymer substrate. The glass substrate may include soda lime glass and the polymer substrate may include polyimide. Further, the support substrate 100 may be rigid or flexible.

The stepped portion 110 is disposed on the support substrate 100. The stepped portion 110 directly makes contact with the support substrate 100. Although the stepped portion 110 is distinguished from the support substrate 100 in the present application for the purpose of convenience of explanation, the embodiment is not limited thereto. For instance, the stepped portion 110 may be integrally formed with the support substrate 100. In detail, the stepped portion 110 can be formed by etching a part of the support substrate 100. For instance, the stepped portion 110 can be formed by patterning the support substrate 100 through the sand blast process.

Referring to FIG. 3, lateral sides of the stepped portion 110 are inclined with respect to the support substrate 100. In detail, the stepped portion 110 may include a first lateral side 111 inclined with respect to the support substrate 100 and a second lateral side 112 inclined with respect to the support substrate 100 corresponding to the first lateral side 111. The first and second lateral sides 111 and 112 are disposed in opposition to each other.

When an inclination angle between the support substrate 100 and the first lateral side 111 is θ₁ and an inclination angle between the support substrate 100 and the second lateral side 112 is θ₂, the inclination angles θ₁and θ₂ may be in the range of about 10 to about 90 respectively. In detail, the inclination angles θ₁and θ₂ may be in the range of about 10 to about 30° respectively, but the embodiment is not limited thereto.

In addition, the inclination angle θ₁ is equal to or different from the inclination angle θ₂. For instance, the inclination angle θ₂ may be larger than the inclination angle θ₁, but the embodiment is not limited thereto.

Further, referring to FIGS. 2 and 3, the lateral sides of the stepped portion are flat, but the embodiment is not limited thereto. For instance, the lateral sides of the stepped portion may be bent or smoothly curved.

The stepped portion 110 has a height h. In detail, the height h of the stepped portion 110 is in the range of about 1.5 μm to about 1 mm, but the embodiment is not limited thereto. Due to the stepped portion 110, the back electrode layer 200, the light absorbing layer 300 and the front electrode layer 600 formed on support substrate 100 may have the height difference. In addition, in the case that the solar cell module is formed by connecting a plurality of solar cells, connection electrodes connecting the solar cells with each other can be almost horizontally connected with each other due to the height h of the stepped portion 110. Thus, the solar cell module according to the embodiment can reduce the contact resistance caused by the bending structure of the connection electrodes and can enlarge the contact area between the connection electrodes, which will be described later in more detail with reference to the solar cell module.

According to one embodiment, when the height of the stepped portion 110 is h, a thickness of the back electrode layer 200 is h_{B}, and a thickness of the light absorbing layer 300 is h_{P}, the height of the stepped portion 110 may be similar to or the same as the sum of the thickness h_{B} of the back electrode layer 200 and the thickness hₚ of the light absorbing layer 300. For instance, the solar cell according to the embodiment may satisfy the equation of h=Y(h_{B}+h_{P}), wherein Y is in the range of about 0.7 to about 1.3, but the embodiment is not limited thereto.

Referring to FIG. 3, a width W1 of a top surface 113 of the stepped portion 110 may be narrower than a width W2 of a bottom surface of the stepped portion 110. The bottom surface of the stepped portion 110 directly makes contact with the support substrate 100.

In addition, although the stepped portion 110 has sharp edges, the embodiment is not limited thereto. For instance, the stepped portion 110 may have curved edges. If the stepped portion 110 has the curved edges, the back electrode layer 200 and the front electrode layer 600 formed on the stepped portion 110 may have the curved shape. Thus, the embodiment can reduce the contact resistance caused by the bending structure of the connection electrode.

The back electrode layer 200 is provided on the support substrate 100 and the stepped portion 110. The back electrode layer 200 is a conductive layer. The back electrode layer 200 may include one selected from the group consisting of molybdenum (Mo), gold (Au), aluminum (Al), chrome (Cr), tungsten (W), and copper (Cu). Among the above materials, the Mo has a thermal expansion coefficient similar to that of the support substrate 100, so the Mo may improve the adhesive property and prevent the back electrode layer 200 from being delaminated from the support substrate 100.

In detail, the back electrode layer 200 directly makes contact with the top surface of the support substrate 100, the top surface of the stepped portion 110 and the lateral side of the stepped portion 110. Meanwhile, referring to FIG. 2, the back electrode layer 200 is disposed only at one lateral side of the stepped portion 110, but the embodiment is not limited thereto. For instance, the back electrode layer 200 can be disposed at both lateral sides of the stepped portion 110.

The back electrode layer 200 may have a first height H1 due to the stepped portion 110. In detail, the back electrode layer 200 may have the height difference due to the stepped portion 110. For instance, the first height H1 is in the range of about 1.5 μm to about 1 mm, but the embodiment is not limited thereto.

The light absorbing layer 300 is provided on the back electrode layer 200. The light absorbing layer 300 includes a group I-III-VI compound. For example, the light absorbing layer 300 may have the CIGSS (Cu(IN,Ga)(Se,S)₂) crystal structure, the CISS (Cu(IN)(Se,S)₂) crystal structure or the CGSS (Cu(Ga)(Se,S)₂) crystal structure. In addition, the light absorbing layer 300 has the bandgap energy in the range of about 1 eV to about 1.8 eV.

The light absorbing layer 300 has a second height H2 due to the stepped portion 110.

In detail, the light absorbing layer 300 may have the height difference due to the stepped portion 110. For instance, the second height H2 is in the range of about 1.5 μm to about 1 mm, but the embodiment is not limited thereto.

The buffer layer 400 is provided on the light absorbing layer 300. The buffer layer 400 may include CdS, ZnS, InₓS_{y} or InₓSe_{y}Zn(O, OH). The buffer layer 400 may have the thickness in the range of about 50 nm to about 150 nm and the energy bandgap in the range of about 2.2 eV to about 2.4 eV.

The high-resistance buffer layer 500 is disposed on the buffer layer 400. The high-resistance buffer layer 500 includes i-ZnO, which is not doped with impurities. The high-resistance buffer layer 500 may have the energy bandgap in the range of about 3.1 eV to about 3.3 eV. The high-resistance buffer layer 600 can be omitted. The buffer layer 400 and the high-resistance buffer layer 500 may have the height difference due to the stepped portion 110, respectively.

The front electrode layer 600 may be provided on the light absorbing layer 300. For example, the front electrode layer 600 may directly make contact with the high-resistance buffer layer 500 formed on the light absorbing layer 300.

The front electrode layer 600 may include a transparent conductive material. In addition, the front electrode layer 600 may have the characteristics of an N type semi-conductor. In this case, the front electrode layer 600 forms an N type semiconductor together with the buffer layer 400 to make a PN junction together with the light absorbing layer 300 serving as a P type semiconductor layer. For instance, the front electrode layer 600 may include aluminum-doped zinc oxide (AZO). The front electrode layer 600 may have a thickness in the range of about 100 nm to about 500 nm.

The front electrode layer 600 may have a third height H3 due to the stepped portion 110. In detail, the front electrode layer 600 may have the height difference due to the stepped portion 110. For instance, the third height H3 is in the range of about 1.5 μm to about 1 mm, but the embodiment is not limited thereto.

FIG. 4 is a sectional view showing the solar cell module according to the embodiment. The above description about the solar cell will be incorporated herein by reference.

Referring to FIG. 4, the solar cell module according to the embodiment includes a support substrate 100, a stepped portion 110, a first solar cell C1 and a second solar cell C2. Although only two solar cells C1 and C2 are shown in FIG. 4, the embodiment is not limited thereto. That is, the solar cell module according to the embodiment may include at least two solar cells.

The first solar cell C1 may include a first back electrode layer 210 formed on the support substrate 100, a first light absorbing layer 310 formed on the first back electrode layer 210, and a first front electrode layer 610 formed on the first light absorbing layer 310. In addition, as shown in FIG. 4, the first solar cell C1 may further include a first buffer layer 410 and a first high-resistance buffer layer 510.

The second solar cell C2 may include a second back electrode layer 220 formed on the stepped portion 110, a second light absorbing layer 320 formed on the second back electrode layer 220, and a second front electrode layer 620 formed on the second light absorbing layer 320. In addition, similar to the first solar cell C1, the second solar cell C2 may further include a second buffer layer 420 and a second high-resistance buffer layer 520.

The first solar cell C1 is electrically connected to the second solar cell C2. In detail, the first and second solar cells C1 and C2 are electrically connected with each other by the first front electrode layer 610 of the first solar cell C1 and the second back electrode layer 220 of the second solar cell C2. In detail, the first front electrode layer 610 of the first solar cell C1 makes contact with the second back electrode layer 220 of the second solar cell C2, so that the first and second solar cells C1 and C2 are electrically connected with each other. That is, the first front electrode layer 610 and the second back electrode layer 220 may serve as connection electrodes, respectively.

As shown in FIG. 4, the first front electrode layer 610 makes contact with the second back electrode layer 220 at the lateral side of the stepped portion 110. Thus, the first and second solar cells C1 and C2 are electrically connected with each other at the lateral side of the stepped portion 110.

The first front electrode layer 610 formed on the support substrate 100 is connected to the second back electrode layer 220 formed on the stepped portion 110 and the bending of the first front electrode layer 610 can be diminished due to the stepped portion 110.

In detail, the first front electrode layer 610 horizontally extends to make contact with the second back electrode layer 220. At this time, the first front electrode layer 610 covers the top surface and the lateral side of the second back electrode layer 220.

As described above, according to the solar cell module of the embodiment, the connection electrodes, which connect the solar cells with each other, are almost horizontally connected with each other due to the height difference of the stepped portion 110, so the contact area between the connection electrodes can be more enlarged. Thus, the solar cell module according to the embodiment can reduce the contact resistance caused by the bending structure of the connection electrode, so that the photoelectric conversion efficiency of the solar cell module can be improved.

As shown in FIG. 4, the first front electrode layer 610 is spaced apart from the second front electrode layer 620. In addition, the first back electrode layer 210 is spaced apart from the second back electrode layer 220. Since the first back electrode layer 210 is spaced apart from the second back electrode layer 220, the solar cell module can be divided into a plurality of solar cells C1 and C2.

Meanwhile, although not shown in the drawings, a polymer resin layer (not shown) and a protective panel (not shown) can be additionally formed on the solar cell module. The polymer resin layer may improve the adhesive strength between the solar cell module and the protective panel and can protect the solar cell module from the external impact. For instance, the polymer resin layer may include an ethylenevinylacetate (EVA) film, but the embodiment is not limited thereto.

The protective panel protects the solar cell module from the external physical impact and/or impurities. The protective panel is transparent and may include tempered glass. For instance, the tempered glass may include low iron tempered glass.

As described above, the solar cell module according to the embodiment includes the stepped portion 110. In addition, due to the stepped portion 110, a roughness pattern can be formed in the solar cell module according to the embodiment. As compared with the solar cell module having no roughness pattern, the solar cell module having the roughness pattern can improve the adhesive strength between the solar cell module and the layers formed on the solar cell module. That is, according to the solar cell module of the embodiment, the adhesive strength between the solar cell module and the polymer resin layer and between the solar cell module and the protective panel can be improved due to the roughness pattern. As a result, the stability and reliability of the solar cell module according to the embodiment can be improved.

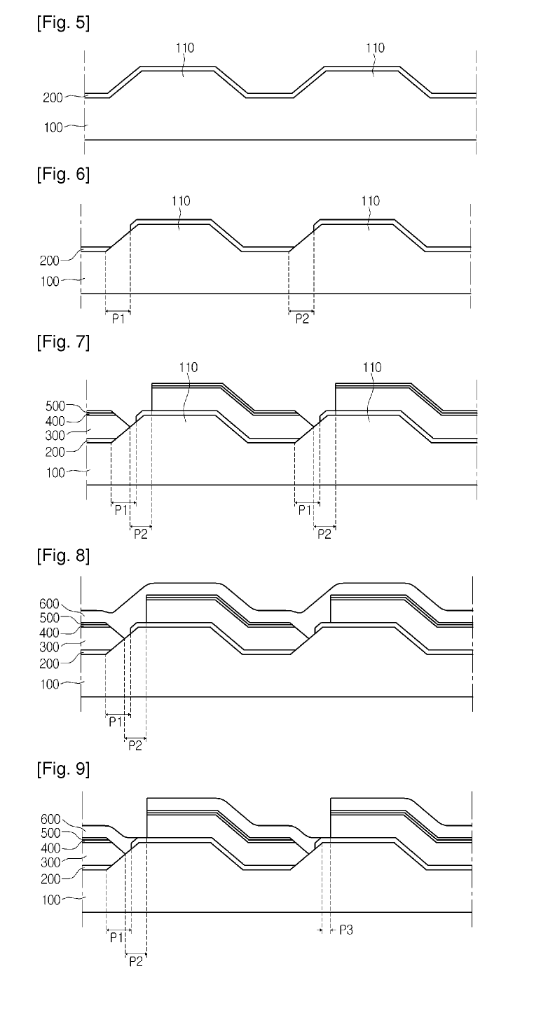

FIGS. 5 to 10 are sectional views showing the method of fabricating the solar cell module according to the embodiment. The above description about the solar cell and the solar cell module will be incorporated herein by reference.

Referring to FIGS. 5 and 6, the back electrode layer 200 is formed on the support substrate 100 including the stepped portion 110. The back electrode layer 220 can be formed by forming a back electrode on the support substrate 100 and then forming a first pattern P1 dividing the back electrode. For instance, the first pattern P1 can be formed through the photolithography process.

The first pattern P1 can be formed on the stepped portion 110. In detail, the first pattern P1 can be formed on the lateral side of the stepped portion 110. In addition, the first pattern P1 may be formed in the vertical direction with respect to the support substrate 100. Otherwise, the first pattern P1 may be inclined with respect to the support substrate 100.

The back electrode layer 200 is divided by the first pattern P1. In detail, the back electrode layer 200 is divided into a plurality of back electrodes by the first pattern P1. For instance, the width of the first pattern P1 may be in the range of about 80 μm to about 200 μm, but the embodiment is not limited thereto.

Referring to FIG. 7, the light absorbing layer 300, the buffer layer 400 and the high-resistance buffer layer 500 are formed on the back electrode layer 200. For instance, the light absorbing layer 300, the buffer layer 400 and the high-resistance buffer layer 500 are sequentially formed on the back electrode layer 200 while making contact with each other.

The light absorbing layer 300 can be formed through the sputtering process or the evaporation process.

In detail, the light absorbing layer 300 may be formed through various schemes such as a scheme of forming a Cu(In,Ga)Se₂(CIGS) based light absorbing layer 300 by simultaneously or separately evaporating Cu, In, Ga, and Se and a scheme of performing a selenization process after a metallic precursor layer has been formed. Regarding the details of the selenization process after the formation of the metallic precursor layer, the metallic precursor layer is formed on the back electrode layer 200 through a sputtering process employing a Cu target, an In target, or a Ga target.

Thereafter, the metallic precursor layer is subject to the selenization process so that the Cu (In, Ga) Se₂ (GIGS) based light absorbing layer 300 is formed.

In addition, the sputtering process employing the Cu target, the In target, and the Ga target and the selenization process may be simultaneously performed.

Further, a CIS or a CIG based light absorbing layer 300 may be formed through the sputtering process employing only Cu and In targets or only Cu and Ga targets and the selenization process.

A second pattern P2 is formed on the light absorbing layer 300, the buffer layer 400 and the high-resistance buffer layer 500. The second pattern P2 is formed on the stepped portion 110. For instance, the second pattern P2 can be formed over the lateral sides and the top surface of the stepped portion 110. In addition, the second pattern P2 can be exclusively formed on the lateral side of the stepped portion 110, but the embodiment is not limited thereto.

The second pattern P2 can be formed through the mechanical scheme such that the back electrode layer 200 can be partially exposed. The second pattern P2 may have a width in the range of about 80 μm to about 200 μm, but the embodiment is not limited thereto. In addition, the second pattern P2 can be formed vertically to the support substrate 100. Otherwise, the second pattern P2 may be inclined with respect to the support substrate 100.

Referring to FIGS. 8 and 9, the front electrode layer 600 is formed on the high-resistance buffer layer 500 by depositing transparent conductive materials on the high-resistance buffer layer 500. The front electrode layer 600 can be formed by forming a front electrode on the light absorbing layer 300 and then forming third patterns P3 for dividing the front electrode. The third patterns P3 can be formed through the mechanical scheme such that the back electrode layer 200 can be partially exposed. The third patterns P3 may have a width in the range of about 80 μm to about 200 μm, but the embodiment is not limited thereto.

Referring to FIG. 9, the third patterns P3 are formed through the light absorbing layer 300, the buffer layer 400, the high-resistance buffer layer 500 and the front electrode layer 600. That is, the solar cells C1 and C2 may be separated from each other by the third patterns P3.

The third pattern P3 can be formed on the stepped portion 110. In detail, the third pattern P3 may be formed on the top surface of the stepped portion 110, but the embodiment is not limited thereto. In addition, the third pattern P3 can be formed vertically to the support substrate 100. Otherwise, the third pattern P3 may be inclined with respect to the support substrate 100.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effects such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. A solar cell comprising:
a stepped portion on a support substrate;
a back electrode layer having a first height difference on the support substrate and the stepped portion;
a light absorbing layer having a second height difference on the back electrode layer; and
a front electrode layer having a third height difference on the light absorbing layer.

2. The solar cell of claim 1, wherein the stepped portion comprises:
a first lateral side inclined with respect to the support substrate; and
a second lateral side inclined with respect to the support substrate in correspondence with the first lateral side.

3. The solar cell of claim 2, wherein, when an inclination angle between the support substrate and the first lateral side is θ₁ and an inclination angle between the support substrate and the second lateral side is θ₂, the inclination angles θ₁ and θ₂ are in a range of about 10 to about 90, respectively.

4. The solar cell of claim 2, wherein a width of a top surface of the stepped portion is narrower than a width of a bottom surface of the stepped portion.

5. The solar cell of claim 2, wherein the back electrode layer are formed on both first and second lateral sides.

6. The solar cell of claim 1, wherein the stepped portion is integrally formed with the support substrate.

7. The solar cell of claim 1, wherein the first to third height differences and a height of the stepped portion are in a range of 1.5 μm to 1 mm, respectively.

8. A solar cell module comprising:
a stepped portion on a support substrate;
a first solar cell on the support substrate; and
a second solar cell on the stepped portion,
wherein the first solar cell is electrically connected to the second solar cell on a lateral side of the stepped portion.

9. The solar cell module of claim 8, wherein the first solar cell comprises a first back electrode layer, a first light absorbing layer and a first front electrode layer sequentially formed on the support substrate, and the second solar cell comprises a second back electrode layer, a second light absorbing layer and a second front electrode layer sequentially formed on the stepped portion.

10. The solar cell module of claim 9, wherein the first front electrode layer is electrically connected to the second back electrode layer by directly making contact with the second back electrode layer on the lateral side of the stepped portion.

11. The solar cell module of claim 9, wherein the first front electrode layer is formed on a lateral side of the second back electrode layer and a top surface of the second back electrode layer.

12. The solar cell module of claim 9, wherein the first front electrode layer horizontally extends to directly make contact with the second back electrode layer.

13. The solar cell module of claim 9, wherein the first front electrode layer is spaced part from the second front electrode layer.

14. The solar cell module of claim 8, wherein the stepped portion comprises:
a first lateral side inclined with respect to the support substrate; and
a second lateral side inclined with respect to the support substrate in correspondence with the first lateral side, and
wherein, when an inclination angle between the support substrate and the first lateral side is θ₁ and an inclination angle between the support substrate and the second lateral side is θ₂, the inclination angles θ₁ and θ₂ are in a range of about 10° to about 90° respectively.

15. A method for fabricating a solar cell module, the method comprising:
forming a back electrode layer on a support substrate including a stepped portion;
forming a light absorbing layer on the back electrode layer; and
forming a front electrode layer on the light absorbing layer.

16. The method of claim 15, wherein the forming of the back electrode layer comprises:
forming a back electrode on the support substrate including the stepped portion; and
forming a first pattern dividing the back electrode on the stepped portion.

17. The method of claim 16, wherein the first pattern is formed on a lateral side of the stepped portion.

18. The method of claim 15, wherein the forming of the light absorbing layer comprises:
forming the light absorbing layer on the back electrode layer; and
forming a second pattern dividing the light absorbing layer on the stepped portion.

19. The method of claim 18, wherein the second pattern is formed on a lateral side of the stepped portion.

20. The method of claim 15, wherein the forming of the front electrode layer comprises:
forming a front electrode on the light absorbing layer; and
forming a third pattern dividing the front electrode on the stepped portion.
